(19) United States
(12) Patent Application Publication
(10) Pub. No.: US 2017/0358691 A1
(43) Pub. Date: Dec. 14, 2017

(54) Reconfigurable MOS Varactor

(71) Applicant: GLOBALFOUNDRIES INC., Grand Cayman (KY)

(72) Inventors: Kai Xiu, Pleasantville, NY (US); Chengwen Pei, Danbury, CT (US); Pinping Sun, Arlington, VA (US)

(21) Appl. No.: 15/181,834

(22) Filed: Jun. 14, 2016

(51) Int. Cl. H01L 29/93; H01L 29/78; H01L 29/08; H01L 29/10; H03L 7/093; H03L 7/099

(52) U.S. Cl. CPC H01L 29/93; H01L 29/0847; H01L 29/1095; H01L 29/1079; H01L 29/78; H03L 7/099; H03L 7/093

(57) ABSTRACT

Various particular embodiments include a semiconductor varactor structure including: a semiconductor substrate of a first conductivity type; a semiconductor area of a second conductivity type, different from the first conductivity type, within the semiconductor substrate; a field effect transistor (FET) structure within the semiconductor area; and a contact, contacting the semiconductor area, for applying a voltage bias to the semiconductor area.

### TECHNICAL FIELD

The subject matter disclosed herein relates to integrated circuits. More particularly, the subject matter relates to high quality (Q) factor metal-oxide semiconductor (MOS) varactors with a large tuning range.

### BACKGROUND

Integrated circuits often include varactors (“variable reactors”). Varactors provide a voltage controlled capacitive element that has a variable capacitance based on the voltage expressed at the terminals and a control voltage. Metal oxide semiconductor (MOS) varactors may have a control voltage applied to a gate terminal that provides a control on the capacitance obtained for a particular voltage applied on the remaining terminals of the device.

Because a varactor is based on a reverse biased P-N junction, the terminals are typically biased such that no current flows across the P-N junction, thereby forming a capacitor. However, varying the bias on the gate of a MOS varactor causes the formation of a depletion or an accumulation region under the gate, changing the current flow through the varactor. The effective capacitance obtained is thus variable, and, voltage dependent. This makes the varactor useful as a voltage controlled capacitor. Varactors are particularly useful in oscillators, RF circuits, mixed signal circuits, and the like.

Two types of conventional MOS varactors are often used. One type is an n-MOS accumulation-type varactor that has a simple implementation. However, in an n-MOS accumulation-type varactor, a parasitic diode is turned on when Vcontrol<0 because the substrate is shorted to ground. This results in a low Q factor during half of the tuning range. The other type is an inversion MOS varactor, which has a parasitic diode that is always reverse biased, preventing leakage to the substrate. However, an inversion MOS varactor has a narrow tuning range.

### SUMMARY

A first aspect provides a semiconductor varactor structure including: a semiconductor substrate of a first conductivity type; a semiconductor area of a second conductivity type, different from the first conductivity type, within the semiconductor substrate; a field effect transistor (FET) structure within the semiconductor area; and a contact, contacting the semiconductor area, for applying a voltage bias to the semiconductor area.

A second aspect provides a system, including: a circuit including at least one variable capacitance; and a varactor device connected to the circuit for providing the at least one variable capacitance, the varactor device including: a semiconductor substrate of a first conductivity type; a semiconductor area of a second conductivity type, different from the first conductivity type, within the semiconductor substrate; a field effect transistor (FET) structure within the semiconductor area; and a contact, contacting the semiconductor area, for applying a voltage bias to the semiconductor area.

A third aspect provides a method for reconfiguring a tuning range of a varactor structure, including: applying a tuning voltage to the varactor structure; applying a back gate voltage bias to the varactor structure; and adjusting at least one of the tuning voltage applied to the varactor structure and the back gate voltage bias applied to the varactor structure to reconfigure the tuning range of the varactor structure.

### BRIEF DESCRIPTION OF THE DRAWINGS

These and other features of this invention will be more readily understood from the following detailed description of the various aspects of the invention taken in conjunction with the accompanying drawings that depict various embodiments of the invention.

FIG. 1 depicts a varactor according to embodiments.

FIG. 2 depicts an equivalent circuit for the varactor of FIG. 1 according to embodiments.

FIG. 3 is a chart depicting tuning voltage versus capacitance for the varactor of FIG. 1 according to embodiments.

FIG. 4 is a chart depicting tuning voltage versus leakage current for the varactor of FIG. 1 according to embodiments.

FIGS. 5-11 depict an example process flow for forming a varactor according to embodiments.

FIGS. 12-16 depict an example process flow for forming a varactor according to embodiments.

FIG. 17 depicts a circuit including at least one varactor according to embodiments.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

As noted above, the subject matter disclosed herein relates to integrated circuits. More particularly, the subject matter relates to high quality factor (Q) metal-oxide semiconductor (MOS) varactors with a large tuning range.

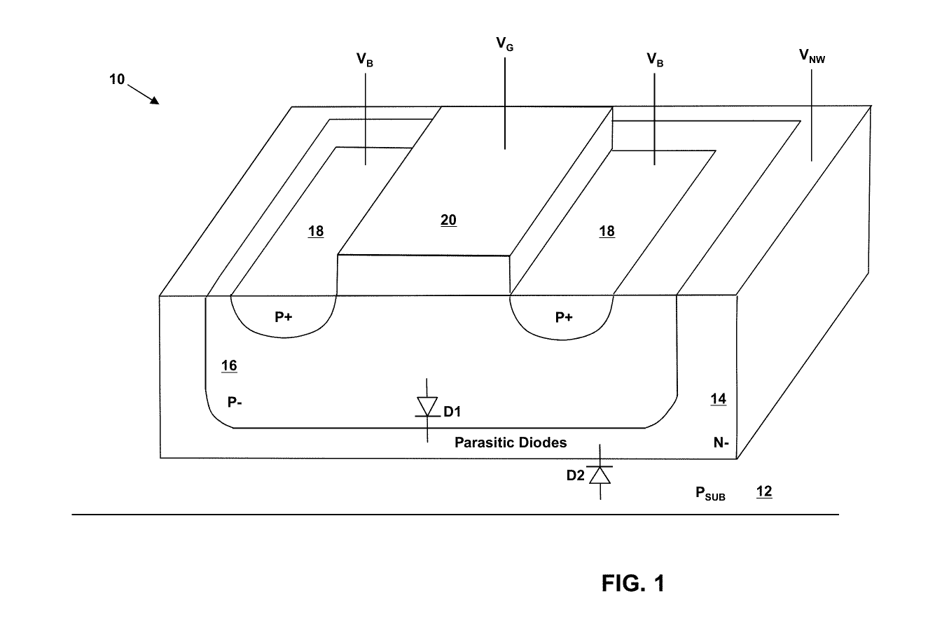

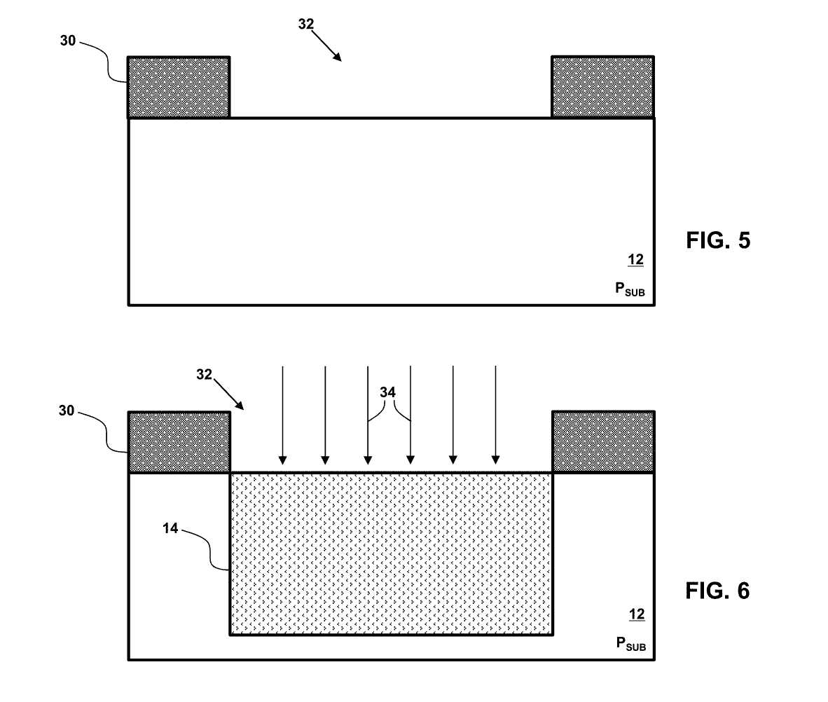

A varactor 10 according to embodiments is depicted in FIG. 1. More specifically, the varactor 10 is a triple well PMOS back gate controlled accumulation P-type varactor. As will be presented in greater detail below, compared to conventional varactors, the configuration of the varactor 10 significantly improves tuning range and provides a superior tuning slope. Parasitic diodes in the varactor 10 are turned off throughout the entire tuning range, thereby reducing power loss. The varactor 10 provides a high quality factor (Q) over the entire tuning range by eliminating parasitic diode current leakage. Processes for forming the varactor 10 according to embodiments are depicted in FIGS. 5-11 and 12-16.

The varactor 10 may be formed, for example, using triple-well MOS technologies. As depicted in FIG. 1, the varactor 10 is formed on a semiconductor substrate 12. The substrate 12 may be formed of silicon (Si), silicon germanium (SiGe), or other suitable semiconductor materials. The substrate 12 may be provided in wafer form, or may be formed using a silicon-on-insulator (SOI) layer. According to embodiments, a P-type substrate 12 is used. The P-type substrate 12 may be formed, for example, by implanting a P-type dopant such as Boron (B) or the like in a semiconductor material.

An N− well 14 is provided in the P-type substrate 12. The N− well 14 may be formed, for example, by implanting an N-type dopant such as Phosphorus (P), Arsenic (As), or the like in a portion of the P-type substrate 12.

A P− well 16 is provided in the N− well 14. The P− well 16 may be formed, for example, by implanting a P-type dopant such as Boron (B), Boron difloride (BF₂), or the like in a portion of the N− well 14. A parasitic diode D1 is present between the P− well 16 and the N− well 14. A parasitic diode D2 is present between the P-type substrate 12 and the N− well 14.

P+ source/drain regions 18 are provided in the P− well 16. The P+ source/drain regions 18 may be formed, for example, by implanting a P-type dopant such as Boron (B), Boron tetrafloride (BF₄), or the like in portions of the P− well 16. The P+ source/drain regions 18 are coupled to a voltage V_{B} via source/drain contacts (not shown). A gate structure 20 is located between the P+ source/drain regions 18. A gate voltage V_{G} is applied to the gate structure 20. The P− well 16, P+ source/drain regions 18, and the gate structure 20 form a field effect transistor (FET)-type structure.

A bias voltage V_{NW} is applied to the N− well 14. By suitably biasing the N− well 14, parasitic diodes in the varactor 10 (e.g., parasitic diodes D1, D2 in FIG. 1) are shut off during the whole tuning range of the varactor 10. This eliminates parasitic diode leakage current, which provides a better Q factor and a larger tuning range. The bias voltage V_{NW} can be considered a back gate voltage.

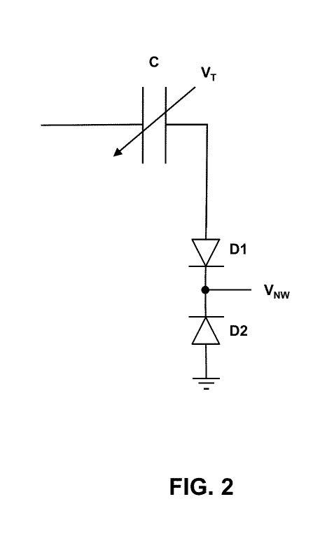

An equivalent circuit of the varactor 10 is depicted in FIG. 2. C is the variable junction capacitance of the varactor 10, which may be tuned by adjusting a tuning voltage V_{T} (i.e., V_{G}−V_{B}) applied between the gate structure 20 and the P+ source/drain regions 18. In operation, the parasitic diodes D1, D2 are shut off when the bias voltage V_{NW} is set to VDD or the maximum tuning voltage V_{T}. Referring to both FIG. 1 and FIG. 2, it can be seen that the voltage V_{T} applied to the P− well 16 may be used to tune the varactor 10 for a given value of V_{NW} (V_{NW} may also be adjusted during tuning).

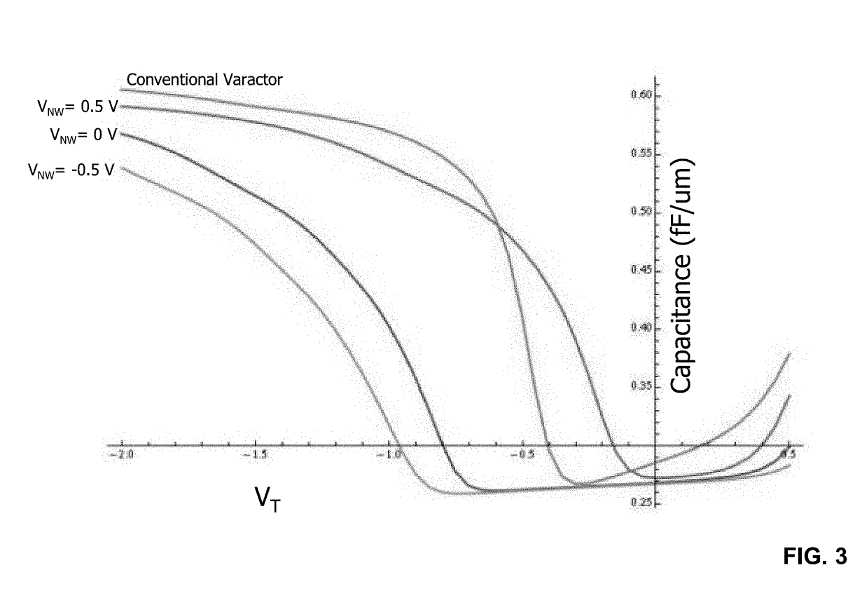

FIG. 3 is a chart depicting tuning voltage V_{T} versus capacitance C for the varactor 10 of FIG. 1 for a plurality of different values of V_{NW}. As shown, when compared to conventional varactor performance, the varactor 10 according to embodiments provides, for example:
1) a much larger tuning range (e.g., ˜10× or more);
2) a superior (more gradual) C−V_{T} slope; and
3) a reconfigurable tuning range based on the value of V_{T} (the tuning range further increases as V_{NW} increases). The capacitance C may be adjusted, for example, to compensate for process variations that may occur during the fabrication of the varactor 10 or other components within a circuit including the varactor 10. The capacitance C may, of course, be adjusted to provide a desired capacitance value within a circuit (e.g., for frequency tuning in a circuit (e.g., a PLL loop), a calibration circuit (e.g., temperature calibration), etc.).

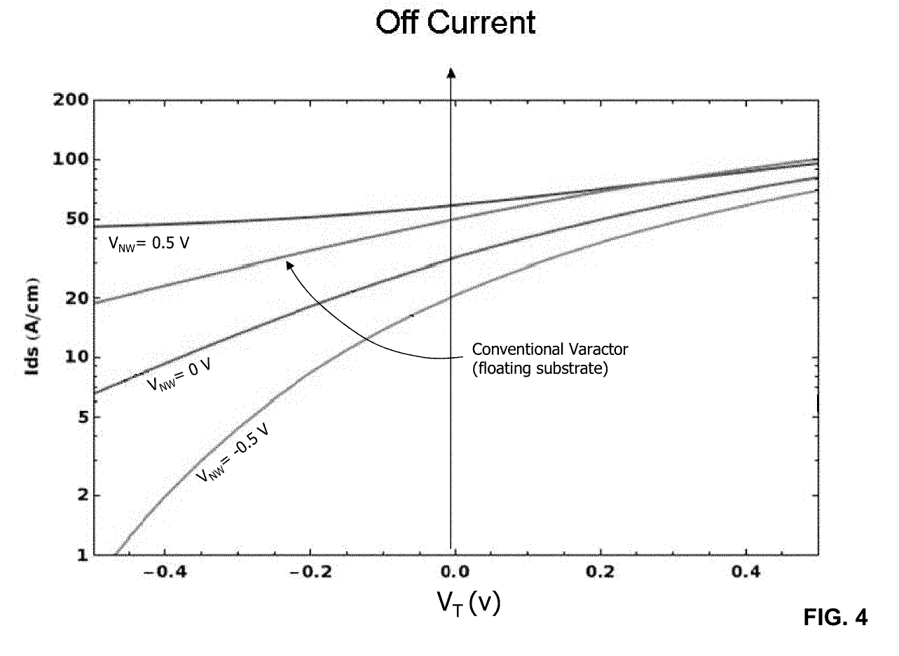

FIG. 4 is a chart depicting gate voltage V_{T} versus leakage (off) current I_{DS} for the varactor 10 of FIG. 1 for a plurality of different values of V_{NW}. As shown, when compared to a conventional varactor, leakage current I_{DS} for the varactor 10 is significantly reduced for certain (e.g., negative) values of V_{NW}. The leakage current I_{DS} (and associated power loss) is reduced, for example, because the parasitic diodes D1, D2 in the varactor 10 are turned off throughout the entire tuning range for certain values of V_{NW}. To this extent, by substantially reducing parasitic diode current leakage I_{DS}, the varactor 10 provides a high quality factor (Q) over the entire tuning range.

An example process flow for forming a varactor 10 according to embodiments is depicted in FIGS. 5-11.

In FIG. 5, a resist 30 is deposited and patterned (e.g., using known deposition and photolithographic processes) on a P-type substrate 12 to form an opening 32 to the P-type substrate 12. The substrate 12 may be formed of silicon (Si), silicon germanium (SiGe), or other suitable semiconductor materials. The substrate 12 may be provided in wafer form, or may be formed using a silicon-on-insulator (SOI) layer. According to embodiments, a P-type substrate 12 is used. The P-type substrate 12 may be formed, for example, by implanting a P-type dopant such as Boron (B) or the like in a semiconductor material.

As used herein, “depositing,” “deposition,” etc., may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The resist 30 (as well as other resists described herein), which may also be referred to as a photoresist, is itself first patterned by exposing it to radiation, where the radiation (selectively) passes through an intervening mask or template containing a pattern. As a result, the exposed or unexposed areas of the resist 30 become more or less soluble, depending on the type of photoresist used. A developer is then used to remove the more soluble areas of the resist leaving a patterned resist 30. The patterned resist 30 can then serve as a mask for the underlying layers (substrate 12 in this case) which can then be selectively treated, such as to receive dopants and/or to undergo etching, for example.

In FIG. 6, an N− well 14 is formed in the P-type substrate 12 by implanting, for example, an N-type dopant 34 such as Phosphorus (P), Arsenic (As), or the like through the opening 32 to the P-type substrate 12. Implantation may be performed, for example, using an ion implanter or other suitable system.

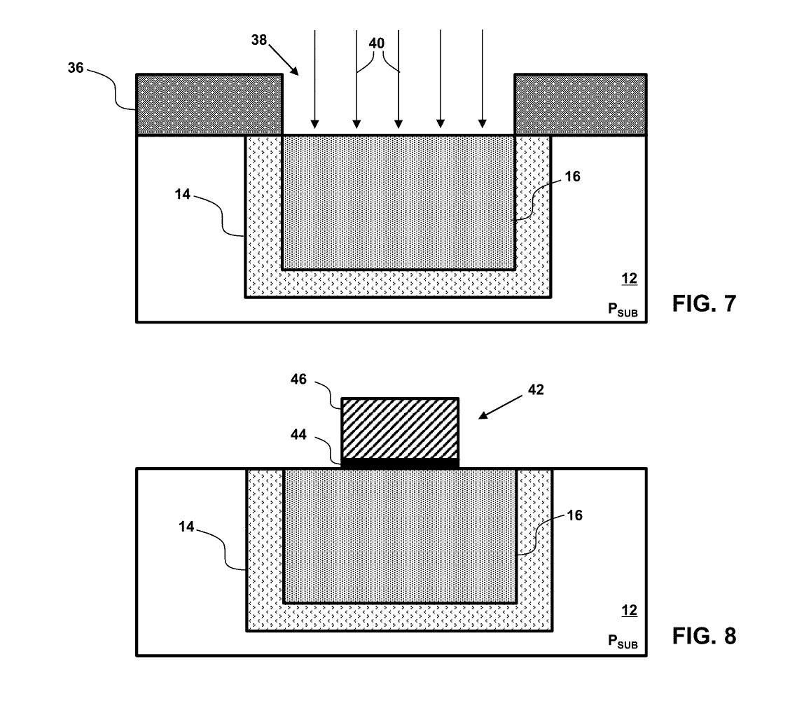

In FIG. 7, a resist 36 is deposited and patterned (e.g., using known deposition and photolithographic processes) to form an opening 38 to the N− well 14. A P− well 16 is then formed in the N− well 14 by implanting, for example, a P-type dopant 40 such as Boron (B), Boron difloride (BF₂), or the like in a portion of the N− well 14. Implantation may be performed, for example, using an ion implanter or other suitable system.

After removal of the resist 36, a gate stack 42 is formed on the P− well 16. The gate stack 42 may comprise, for example, a gate insulator 44 formed on the P− well 16 and a gate conductor 46 formed on the gate insulator 44. The gate insulator 44 and gate conductor 46 may be formed using known deposition and photolithographic processes.

According to embodiments, the gate insulator 44 may be formed of a high-k material, while the gate conductor 46 may be formed of polysilicon or other suitable material. The gate insulator 44 may be formed, for example, using a thermal growing process such as, for example, oxidation, nitridation or oxynitridation. Alternatively, the gate insulator 44 can be formed by a deposition process such as, for example, chemical vapor deposition (CVD), plasma-assisted CVD, atomic layer deposition (ALD), evaporation, reactive sputtering, chemical solution deposition and other like deposition processes. The gate insulator 44 may also be formed utilizing any combination of the above processes. Examples of high-k materials include, but are not limited to, metal oxides such as tantalum oxide (Ta₂O₅), barium titanium oxide (BaTiO₃), hafnium oxide (HfO₂), zirconium oxide (ZrO₂), and aluminum oxide (Al₂O₃), or metal silicates such as hafnium silicate oxide (Hf_{A1}Si_{A2}O_{A3}) or hafnium silicate oxynitride (Hf_{A1}Si_{A2}O_{A3}N_{A4}), where A1, A2, A3, and A4 represent relative proportions, each greater than or equal to zero and A1+A2+A3+A4 (1 being the total relative mole quantity).

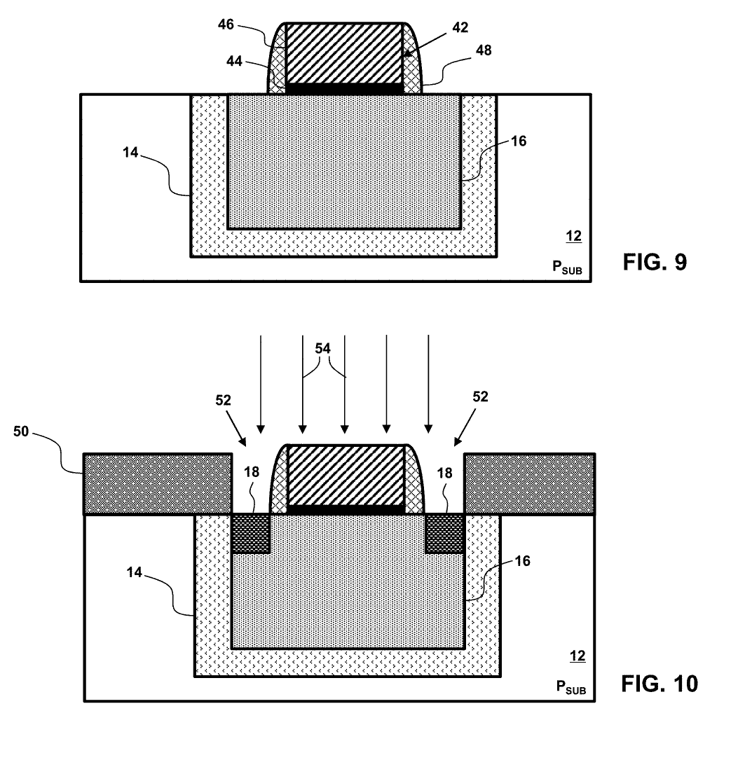

In FIG. 9, at least one spacer 48 is formed on exposed sidewalls of the gate stack 41 The spacer 48 may be formed of an insulator such as an oxide, nitride, oxynitride, and/or any combination thereof. The spacer 48 may be formed using known deposition and photolithographic processes.

In FIG. 10, a resist 50 is deposited and patterned (e.g., using known deposition and photolithographic processes) to form openings 52 to the P− well 16. P+ source/drain regions 18 are then formed in the P− well 16 by implanting, for example, a P-type dopant 54 such as Boron (B), Boron tetrafluoride (BF₄) or the like in the P− well 16 on adjacent sides of the gate stack 42. Implantation may be performed, for example, using an ion implanter or other suitable system. After implantation, the resist 50 is removed.

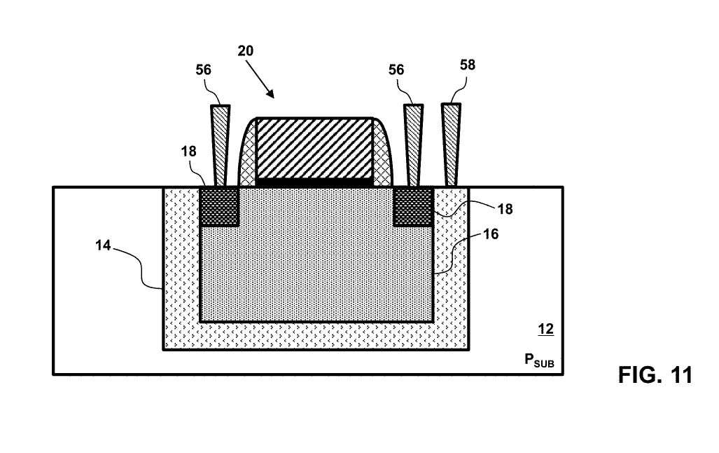

In FIG. 11, a contact 56 is formed on each of the P+ source/drain regions 18. Further, a contact 58 is formed on the N− well 14. The contacts 56, 58 may be formed using known deposition and photolithographic processes. Comparing FIGS. 1 and 11, it can be seen that the voltage V_{B} is applied to the P+ source/drain regions 18 via the contacts 56, while the voltage V_{G} is applied to the gate conductor regions 18 via the contact 58.

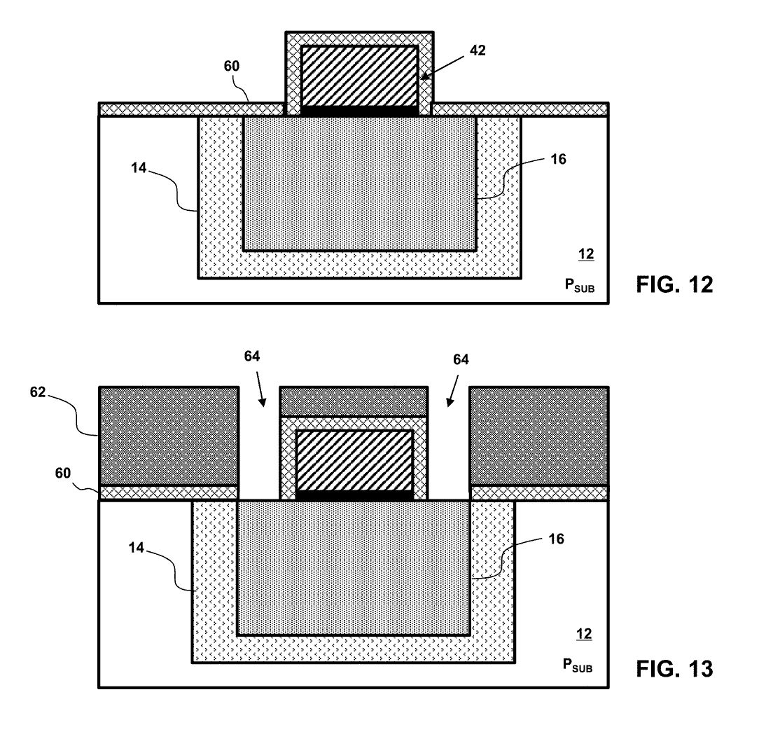

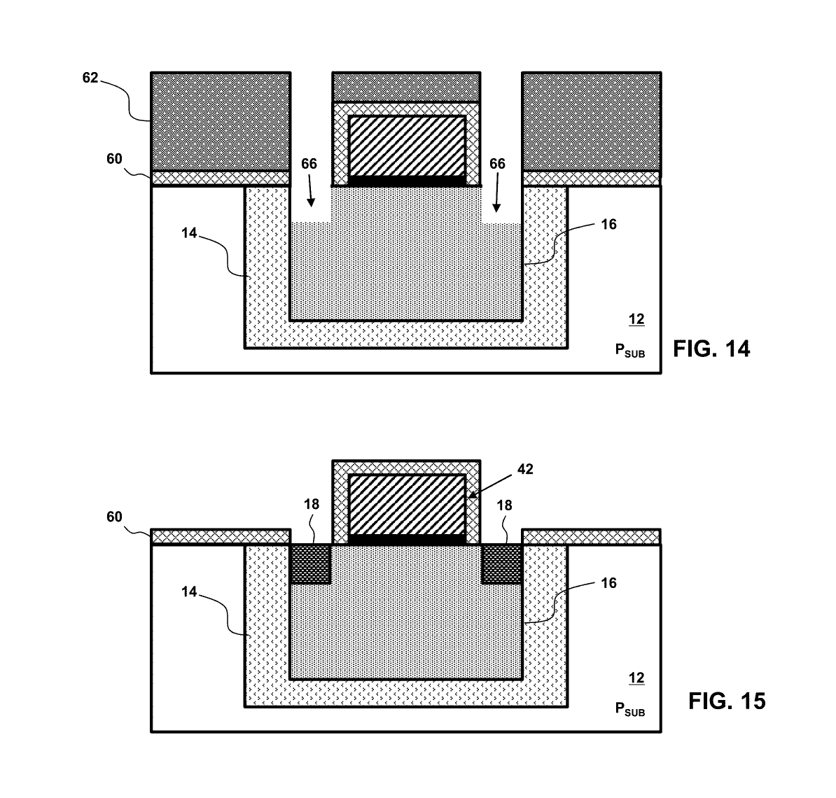

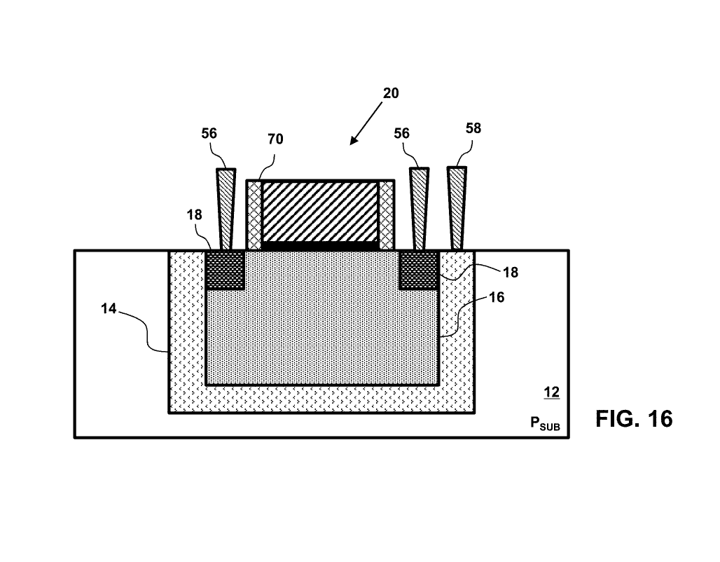

Other processes may be used to form the varactor 10. For example, as shown in FIG. 12, a conformal layer 60 (e.g., silicon nitride) may be deposited in a known manner on the structure depicted in FIG. 8. A resist 62 may then be deposited on the conformal layer 60 and patterned to create openings 64 to the P− well 16 as depicted in FIG. 13. An etching process may then be performed to create recesses 66 in the P− well 16 as shown in FIG. 14. The recesses 66 are filled with a semiconductor material and doped with a P-type dopant to form P+ source/drain regions 18. The resulting structure after removal of the resist 62 is shown in FIG. 15. The semiconductor material may include, for example, epitaxially grown silicon germanium (SiGe) doped in situ with, for example, Boron (B), Boron tetrafluoride (BF₄) or the like. The conformal layer 60 is selectively removed to form spacers 70 on the sidewalls of the gate stack 42, and contacts 56, 58 are formed to provide the varactor 10 shown in FIG. 16.

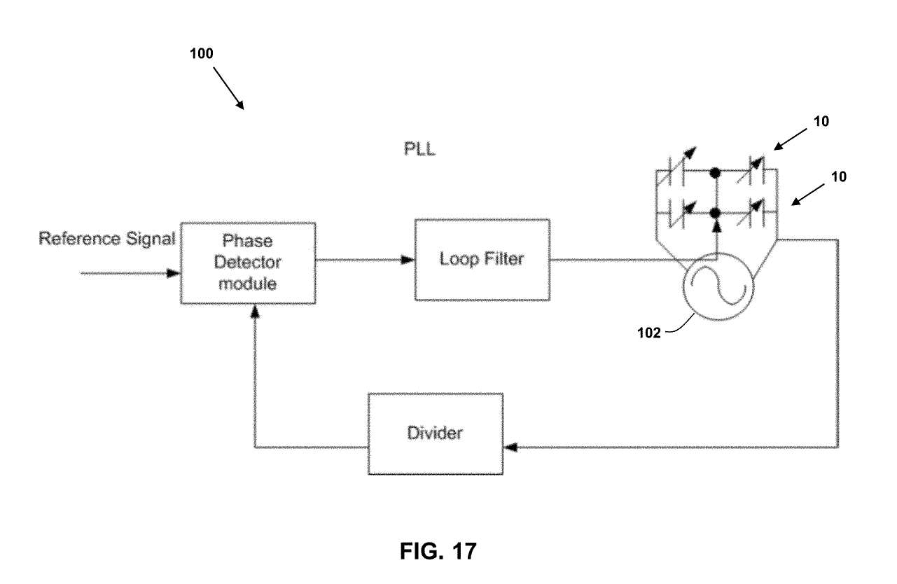

As detailed above with regard to FIG. 1, the tuning voltage V_{T} applied to the P− well 16 may be used to tune the varactor 10. To this extent, the input (e.g., the tuning voltage V_{T}) of the varactor 10 may be provided by another circuit. For example, as depicted in FIG. 17, one or more varactors 10 may be used in a phase locked loop (PLL) circuit 100 to control a voltage controlled oscillator 102.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

We claim:

1. A semiconductor varactor structure, comprising:
a semiconductor substrate of a first conductivity type;
a semiconductor area of a second conductivity type, different from the first conductivity type, within the semiconductor substrate;
a field effect transistor (FET) structure within the semiconductor area; and
a contact, contacting the semiconductor area, for applying a voltage bias to the semiconductor area.

2. The semiconductor varactor structure according to claim 1, further comprising at least one parasitic diode, wherein the voltage bias, when applied to the contact, turns off the at least one parasitic diode.

3. The semiconductor varactor structure according to claim 1, further comprising at least one parasitic diode, wherein the voltage bias, when applied to the contact, reduces leakage current in the at least one parasitic diode.

4. The semiconductor varactor structure according to claim 1, wherein the first conductivity type comprises a P-type dopant, and wherein the second conductivity type comprises an N-type dopant.

5. The semiconductor varactor structure according to claim 1, wherein the FET structure comprises:
a semiconductor well of the first conductivity type within the semiconductor area;
source and drain regions within in the semiconductor well; and
a gate structure on the semiconductor well.

6. The semiconductor varactor structure according to claim 5, wherein the source and drain regions are of the first conductivity type.

7. The semiconductor varactor structure according to claim 6, wherein the FET structure further comprises a plurality of contacts for applying a tuning voltage to the FET structure.

8. The semiconductor varactor structure according to claim 6, wherein the FET structure further comprises a reconfigurable tuning range based on values of the bias voltage and the tuning voltage.

9. A system, comprising:
a circuit including at least one variable capacitance; and
a varactor device connected to the circuit for providing the at least one variable capacitance, the varactor device including:
a semiconductor substrate of a first conductivity type;
a semiconductor area of a second conductivity type, different from the first conductivity type, within the semiconductor substrate;
a field effect transistor (FET) structure within the semiconductor area; and
a contact, contacting the semiconductor area, for applying a voltage bias to the semiconductor area.

10. The system according to claim 9, the varactor device further comprising at least one parasitic diode, wherein the voltage bias, when applied to the contact via the contact, turns off the at least one parasitic diode.

11. The system according to claim 9, the varactor device further comprising at least one parasitic diode, wherein the voltage bias, when applied to the contact via the contact, reduces leakage current in the at least one parasitic diode.

12. The system according to claim 9, wherein the first conductivity type comprises a P-type dopant, and wherein the second conductivity type comprises an N-type dopant.

13. The system according to claim 9, wherein the FET structure comprises:
a semiconductor well of the first conductivity type within the semiconductor area;
source and drain regions within the semiconductor well; and
a gate structure on the semiconductor well.

14. The system according to claim 13, wherein the source and drain regions are of the first conductivity type.

15. The system according to claim 13, wherein the FET structure further comprises a plurality of contacts for applying a tuning voltage to the FET structure.

16. The system according to claim 15, wherein the FET structure further comprises a reconfigurable tuning range based on values of the bias voltage and the tuning voltage.

17. A method for reconfiguring a tuning range of a varactor structure, comprising:
applying a tuning voltage to the varactor structure;
applying a back gate voltage bias to the varactor structure; and
adjusting at least one of the tuning voltage applied to the varactor structure and the back gate voltage bias applied to the varactor structure to reconfigure the tuning range of the varactor structure.

18. The method according to claim 17, wherein the varactor structure comprises:
a semiconductor substrate of a first conductivity type;
a semiconductor area of a second conductivity type, different from the first conductivity type, within the semiconductor substrate; and
a field effect transistor (FET) structure within the semiconductor area;
wherein applying the back gate voltage bias to the varactor structure comprises applying the back gate voltage to the semiconductor area of the second conductivity type.
